(19) United States
(12) Patent Application Publication
(10) Pub. No.: US 2025/0327165 A1
(43) Pub. Date: Oct. 23, 2025

(54) TRANSITION METAL DI-CHALCOGENIDES

(71) Applicant: Monash University, Clayton, Victoria (AU)

(72) Inventors: Sudha MOKKAPATI, Clayton, Victoria (AU); Mohammad Mosarof HOSSAIN, Clayton, Victoria (AU)

(21) Appl. No.: 18/870,954

(22) PCT Filed: Jun. 1, 2023
(86) PCT No.: PCT/AU2023/050475

§ 371 Date: Dec. 2, 2024

(30) Foreign Application Priority Data
Jun. 2, 2022 (AU) 2022901520

(51) Int. Cl. C23C 14/06; B82Y 30/00; B82Y 40/00; C23C 14/30; C23C 14/54; C23C 14/58; G01N 27/30; H10D 64/23

(52) U.S. Cl. CPC C23C 14/0623; C23C 14/30; C23C 14/541; C23C 14/5806; G01N 27/30; H10D 64/251; B82Y 30/00; B82Y 40/00

(57) ABSTRACT

Disclosed herein is a structure comprising a substrate having a polycrystalline transition metal di-chalcogenide nanolayer disposed on a substrate surface, wherein the polycrystalline transition metal di-chalcogenide nanolayer has a surface, and a portion of the plurality of grains project out of plane from the surface.

### FIELD

The invention relates to transition metal di-chalcogenides, methods of production thereof, and uses thereof.

### BACKGROUND

Transition metal di-chalcogenides (TMDC) materials are of increasing economic interest due to their higher conductivity, high carrier mobility, and their tunable electrical properties and bandgap. Given these desirable properties, TMDC materials find a variety of uses in electronics, for example as transistors or as electrical sensors.

Presently, and to the inventor's knowledge, there has been limited uptake of TMDC materials in electronic devices due to costly and difficult fabrication procedures. In particular, using current fabrication technologies, it is generally only possible to make very small single crystal films of TMDC materials. Given these limitations, TMDC materials have found little commercial uptake.

It is an object of the invention to address at least one shortcoming of the prior art and/or provide a useful alternative.

Reference to any prior art in the specification is not an acknowledgment or suggestion that this prior art forms part of the common general knowledge in any jurisdiction or that this prior art could reasonably be expected to be understood, regarded as relevant, and/or combined with other pieces of prior art by a skilled person in the art.

### SUMMARY OF INVENTION

In a first aspect of the invention there is provided a structure comprising a substrate having a polycrystalline transition metal di-chalcogenide nanolayer disposed on a substrate surface, wherein the polycrystalline transition metal di-chalcogenide nanolayer has a surface, and a portion of the plurality of grains project out of plane from the surface.

Traditional approaches towards forming metal di-chalcogenide layers have focused on providing these in the form of single crystal monolayers with a smooth surface. This is generally because the presence of grains and grain boundaries has a deleterious effect on the desired properties of the resultant metal di-chalcogenide layer. The inventors have unexpectedly found that in some cases, the additional surface area provided by polycrystalline transition metal di-chalcogenide layer with grains that project out of plane from the surface is beneficial, e.g. particularly for increasing surface density of any probes bonded to the surface.

In an embodiment, the polycrystalline transition metal di-chalcogenide nanolayer is formed from a plurality of grains, the plurality of grains having a D50 of from about 20 nm up to about 400 nm. Preferably, the D50 is from about 50 nm. More preferably, the D50 is from about 100 nm. Most preferably, the D50 is from about 150 nm. Alternatively, or additionally, the D50 is up to about 350 nm. More preferably, the D50 is up to about 300 nm. Most preferably, the D50 is up to about 250 nm.

In an embodiment, the polycrystalline transition metal di-chalcogenide nanolayer has an average thickness of from about 4 nm up to about 20 nm. Preferably from about 6 nm. More preferably from about 8 nm. Additionally, or alternatively, the average thickness is preferably up to about 18 nm. More preferably, up to about 16 nm. Even more preferably, up to about 14 nm. Most preferably, up to about 12 nm.

In an embodiment, the polycrystalline transition metal di-chalcogenide nanolayer is substantially continuous. By continuous it is meant that the grains are substantially in contact with one another and the layer is substantially free of pin hole defects.

In an embodiment, the polycrystalline transition metal di-chalcogenide nanolayer is formed from a transition metal di-chalcogenide of the form MX₂, where M represents a transition metal selected from the group consisting of: Mo, Pt, Sn, W, and Zr, and X represents a chalcogenide selected from the group consisting of: S, Se, and Te.

In an embodiment, the substrate is an electrically insulating material. Preferably, the substrate is selected from the group consisting of silica, alumina, silicon, glass, or a polymer. However, in other embodiments, the skilled person will appreciate that the substrate may be a dielectric material or a metal.

In an embodiment, the substrate has a planar surface, and the polycrystalline transition metal di-chalcogenide nanolayer is disposed on the planar surface. However, in an alternative embodiment, the substrate has a 3D structure with a non-planar surface, and the polycrystalline transition metal di-chalcogenide nanolayer is disposed on the non-planar surface.

In an embodiment, the polycrystalline transition metal di-chalcogenide nanolayer has a surface roughness of from about 0.5 nm up to about 2 nm. Preferably, the surface roughness is from about 0.6 nm. More preferably, the surface roughness is from about 0.7 nm. Most preferably, the surface roughness is from about 0.8 nm. Alternatively, or additionally, it is preferred that the surface roughness is up to about 1.8 nm. More preferably, the surface roughness is up to about 1.6 nm. Most preferably, the surface roughness is up to about 1.4 nm. In one example, the preferred surface roughness is from about 0.8 nm up to about 1.4 nm.

In a second aspect of the invention there is provided a device comprising:
the structure according to the first aspect of the invention and/or embodiments thereof;
a source electrode; and
a drain electrode;
wherein the source and drain electrode are separated from one another by, and are each arranged in electrical contact with, the polycrystalline transition metal di-chalcogenide nanolayer.

In the case of the above, the structure acts as a channel layer between the source electrode and the drain electrode. It is preferred that the channel layer defines a channel length of from about 15 μm to about 25 μm between the source electrode and the drain electrode.

In an embodiment, the structure further comprises a gate electrode to apply a gate voltage to or across the structure. Preferably, the gate electrode is separated from the structure by a layer of a dielectric or insulating material.

In one form of the above embodiment, the device is a field effect transistor.

In an embodiment, a surface of the polycrystalline transition metal di-chalcogenide nanolayer is functionalized with a probe for detection of an analyte.

In one form of the above embodiment, the probe is configured to alter electron mobility and/or conductivity and/or transconductance of the polycrystalline transition metal di-chalcogenide nanolayer on detection or the analyte. That is, when the analyte binds or interacts with the probe, the analyte attracts/repels electrons, causing a change in the electron mobility or the conductivity or the transconductance of the polycrystalline transition metal di-chalcogenide nanolayer.

In one form of the above embodiment, the probe is selected from the group of: a ligand, a surfactant, a nanoparticle, a polymer, an oligomer, an antibody, gas molecules, or a combination thereof.

The inventors have found that polycrystalline transition metal di-chalcogenide nanolayer are useful in such devices, i.e. from about 4 nm up to about 20 nm. In contrast, for Si-based devices, an Si layer in the range of microns is required. Given this, the use of polycrystalline transition metal di-chalcogenide nanolayers allows for flexible and wearable devices. Accordingly, embodiments of the second aspect of the invention, the device is a wearable and/or flexible device.

In a third aspect of the invention, there is provided an assay method comprising:
using the structure according to the first aspect of the invention and/or embodiments thereof to detect an analyte; or
using the device according to the second aspect of the invention and/or embodiments thereof and/or forms thereof to detect an analyte.

In an embodiment, the method further comprises:
contacting a sample receiving surface of the structure or device with a sample;
measuring electron mobility of the polycrystalline transition metal di-chalcogenide nanolayer; and
determining the presence of the analyte in the sample based on a change in the electron mobility of the polycrystalline transition metal di-chalcogenide nanolayer.

In one form of the above embodiment, the sample receiving surface is a surface of the polycrystalline transition metal di-chalcogenide nanolayer. In another embodiment, the sample receiving surface is one or more probes adhered to the polycrystalline transition metal di-chalcogenide nanolayer.

In a fourth aspect of the invention, there is provided a method for forming a structure comprising a polycrystalline transition metal di-chalcogenide nanolayer, the method comprising:
providing a structure having a transition metal surface;
depositing a chalcogenide on the transition metal surface under an atmosphere at a deposition temperature in the range of 300° C. to 500° C.; and
annealing the chalcogenide on the transition metal surface at a temperature in the range of 300° C. to 500° C. for a time sufficient to form the polycrystalline transition metal di-chalcogenide nanolayer.

In an embodiment, the step of depositing the chalcogenide on the transition metal surface comprises entraining the chalcogenide in a carrier gas stream at a first temperature and at a first location, transporting the chalcogenide in the carrier gas stream to the transition metal surface, and depositing the chalcogenide on the transition metal surface at a second temperature that is lower than the first temperature. Preferably, the first temperature is above a vaporization temperature of the chalcogenide and the second temperature is below a vaporization temperature of the chalcogenide.

In an embodiment, the step of depositing the chalcogenide on the transition metal surface is a physical vapor deposition process. Preferably an electron-beam physical vapor deposition process.

In an embodiment the atmosphere/carrier gas is an inert gas or a mixture of an inert gas with hydrogen. Hydrogen has advantageously been found to influence the bonding between the transition metal and the dichalcogenide and influences the stoichiometry and surface roughness of the resultant polycrystalline transition metal di-chalcogenide nanolayer. A preferred inert gas is nitrogen or argon.

In an embodiment, the structure further comprises a substrate. Preferably, the method comprises depositing a transition metal on a surface of the substrate with a carrier gas at a temperature in the range of 300° C. to 500° C. to form the structure having a transition metal surface. Preferably, the step of depositing the transition metal is conducted at a temperature below the vaporization temperature of the transition metal. Preferably, the transition metal layer is about 1 to 5 nm thick.

In one form of the above embodiment, the carrier gas is an inert gas or a mixture of an inert gas with hydrogen. A preferred inert gas in nitrogen or argon.

In an embodiment, the step of depositing the transition metal of the substrate surface is a physical vapor deposition process. Preferably an electron-beam physical vapor deposition process.

In an embodiment, the annealing temperature is higher than the deposition temperature.

In a fifth aspect of the invention, there is provided the use of the structure according to the first aspect of the invention and/or embodiments thereof or of the device according to the second aspect of the invention and/or embodiments thereof and/or forms thereof as a sensor. The sensor may be, for example, a biosensor, a gas detection sensor, a photonics sensor, or an optoelectronic sensor.

Preferably, the structure or device is used as a sensor for detecting the presence of an analyte, such as in a sample. Such analytes include: cancer markers, cardiac disease markers, food and/or water contaminants, biological hazards, and pollutants.

In a sixth aspect of the invention, there is provided the use of the structure according to the first aspect of the invention and/or embodiments thereof or of the device according to the second aspect of the invention and/or embodiments thereof as a catalyst, in petrochemical water splitting, in thermoelectric applications, in photodetection, as or in an energy storage device, as or in a super-capacitor, as an optoelectronic device such as a laser or spaser.

Further aspects of the present invention and further embodiments of the aspects described in the preceding paragraphs will become apparent from the following description, given by way of example and with reference to the accompanying drawings.

As used herein, except where the context requires otherwise, the term “comprise” and variations of the term, such as “comprising”, “comprises” and “comprised”, are not intended to exclude further additives, components, integers or steps.

### BRIEF DESCRIPTION OF DRAWINGS

FIG. 1: Schematic representation of PtTe₂ layer formation via a process according to an embodiment of the invention.

FIG. 2: AFM images showing surface morphology and grain size changes in Pt film, PtTe film, and PtTe₂ layer. Scale bar represents 50 nm.

FIG. 3: Planar and 3D AFM images showing surface morphology and grain size in PtTe₂ layer according to one sample. The 3D image shows out of plane orientation of the grains. PtTe₂ is obtained from a Pt layer thickness of 1.8 nm. The color scale varies between −10 nm and 5 nm.

FIG. 4: 3D AFM image showing surface morphology and grain size in PtTe₂ layer according to another sample different from that of FIG. 3. The image shows out of plane orientation of the grains. PtTe₂ is obtained from a Pt layer thickness of 1.2 nm. The color scale varies between −5 nm and 3 nm.

FIG. 5: Thickness measurement of Pt film on SiO₂/Si surface.

FIG. 6: Thickness measurement of PtTe₂ layer on SiO₂/Si surface.

FIG. 7: Raman spectrum of before and after annealing PtTe layer to form the PtTe₂ layer.

FIG. 8: Graph showing transfer characteristics curve of fabricated PtTe₂ device at constant drain source voltage is 0.05 V where inset optical images of PtTe₂ FET device.

FIG. 9: Graph showing output characteristics curve of PtTe₂ FET device at −0.1 to 0.1 drain-source voltage.

FIG. 10: Schematic illustration of PtTe₂ FET device fabrication, surface modification, immobilization and detection of AFP concentration.

FIG. 11: Image showing APTES modified PtTe₂ surface.

FIG. 12: Raman spectrum before and after PtTe₂ surface modification with APTES and functionalization with AuNPs.

FIG. 13: AFM images of AuNPs functionalized PtTe₂ conducting surface.

FIG. 14: SEM images of AuNPs functionalized PtTe₂ conducting surface.

FIG. 15: Graph showing transfer characteristics of PtTe₂ sensor before and after APTES modification, AuNPs functionalization, anti-AFP immobilization and non-specific casein blocking with the variation of back gate voltage from −4 to 2 V at 0.05 of constant drain-source voltage.

FIG. 16: Graph showing transfer characteristics of PtTe₂ FET sensor for specificity and selectiveness with the variation of HAS concentration as function of gate voltage from −4 to 2 V at constant drain-source voltage of 0.05 V.

FIG. 17: Schematic illustration of AFP detection with PtTe₂ FET device.

FIG. 18: Graph showing transfer characteristics of PtTe₂ sensor when interacting different concentration of AFP protein from 1 fg mL⁻¹-1 ng mL⁻¹ as a function of gate voltage is −4 V˜2 V at constant drain-source voltage is 0.05 V.

FIG. 19: Graph showing the average change in threshold voltage as a function of AFP proteins concentration in PBS solution.

FIG. 20: Graph showing average sensitivity of PtTe₂ FET sensor as a function of AFP concentration.

FIG. 21: Graph showing output characteristics of lower AFP concentration of 1 fg mL⁻¹ with the variation of gate voltage −2 to 2 V in 0.4 steps.

FIG. 22: Graph showing output characteristics curve of PtTe2 FET sensor for different AFP concentration.

FIG. 23: Graph showing time-dependent response of PtTe₂ FET sensor for the AFP concentration from 1 fg mL⁻¹ to 10 ng mL⁻¹ at 50 mV of drain-source voltage.

FIG. 24: Graph showing average sensitivity of PtTe₂ sensor based on time-dependent as a function of AFP concentration.

FIG. 25: Graph showing stabilized current with the variation of AFP concentration and time range from 100-200 s.

FIG. 26: Graph showing the response of PtTe₂ sensor as function of AFP concentration and stabilized current.

FIG. 27: Image showing 1 mm×1 mm film of PtTe₂ deposited on substrate with electrical contacts for use in sensor testing.

FIG. 28: Raman spectra confirming formation of PtTe₂ layer in FIG. 27.

FIG. 29: Graph showing electrical sensitivity of FET containing channel formed from a layer of PtTe₂ which has been functionalized with Au/Pd nanoparticles.

FIG. 30: Graph showing electrical sensitivity of FET containing channel formed from a layer of Silicon which has been functionalized with Au/Pd nanoparticles.

FIG. 31: Graph showing electrical sensitivity to NH₃ gas of FET containing channel formed from a layer of Silicon which has been functionalized with Au/Pd nanoparticles.

FIG. 32: Graph showing electrical sensitivity to H₂S gas of FET containing channel formed from a layer of Silicon which has been functionalized with Au/Pd nanoparticles.

FIG. 33: Graph showing electrical sensitivity to NH₃ gas of FET containing channel formed from a layer of PtTe₂ which has been functionalized with CuO nanoparticles.

FIG. 34: Graph showing electrical sensitivity to H₂S gas of FET containing channel formed from a layer of PtTe₂ which has been functionalized with CuO nanoparticles.

### DESCRIPTION OF EMBODIMENTS

The invention relates to a structure comprising a substrate having a polycrystalline transition metal di-chalcogenide nanolayer disposed thereon. The polycrystalline transition metal di-chalcogenide nanolayer is formed from grains, and a plurality of the grains project in a direction out of plane from a surface of the nanolayer.

The term “nanolayer” is generally intended to refer to a layer that has a thickness within the order of nanometers. In preferred forms, the nanolayer has a thickness of about 4 to 20 nm.

In a departure from conventional approaches, which are directed toward the production of transition metal di-chalcogenide in the form of smooth single crystal monolayers, the inventors have unexpectedly found that the provision of a rough polycrystalline surface has a number of advantages over single crystal monolayers. Generally, smooth single crystal monolayers since these provide easily controllable and measurable electronic properties. In contrast, grain boundaries are thought to impede electrical properties such as conductivity. Notwithstanding this, the inventors have unexpectedly found that the increased surface are provided by the rough surface (e.g. grains projecting out of surface plane) obviates some of these disadvantages and additionally, in situations where the transition metal di-chalcogenide is used as a sensor element, provides a template for high density adsorption or attachment of probes to increase sensor resolution and detection limits.

Advantageously, the structure of the invention finds particular use as a component of an electrical device such as a transistor or sensor.

The inventors have also developed a method for forming the above-mentioned structure. Typical approaches to forming transition metal di-chalcogenide, such as the aforementioned smooth single crystal monolayers, require high processing temperatures and are generally only suited to forming small area layers (of the order of microns) on flat 2D substrates.

The method adopts significantly lower temperatures and can be used to form large area sheets of the polycrystalline transition metal di-chalcogenide nanolayer of the invention and can be easily adapted to coat 3D substrates.

The method generally comprises providing a structure with a transition metal surface (which may also include initially coating that structure with the transition metal to form the transition metal surface, such as by using a physical vapor deposition process), depositing a chalcogenide on the transition metal surface under an atmosphere at a deposition temperature in the range of 300° C. to 500° C., and subsequently annealing the chalcogenide on the transition metal surface at a temperature in the range of 300° C. to 500° C. for a time sufficient to form the polycrystalline transition metal di-chalcogenide layer.

The invention will now be described with reference to specific embodiments below of a PtTe2 transition metal dichalcogenide (TDMC). However, the skilled person will appreciate that other TDMC materials are contemplated.

### Example 1

This example reports the fabrication of a TMDC (PtTe₂) layer and the characterisation thereof.

A 1.2 nm thick Pt film was deposited on a 50 μm by 50 μm size patterned area of a 285 nm thick SiO₂/Si substrate via ebeam evaporation using a 0.1 Å deposition rate. The Pt layer thickness was confirmed with atomic force microscopy (AFM).

The Pt deposited SiO₂/Si substrate was then placed in a quartz tube downstream of a source of Te powder. The Pt deposited SiO₂/Si substrate was held at a temperature of 300° C. The Te powder was contained within a quartz boat at an upstream location with a temperature of 430° C.

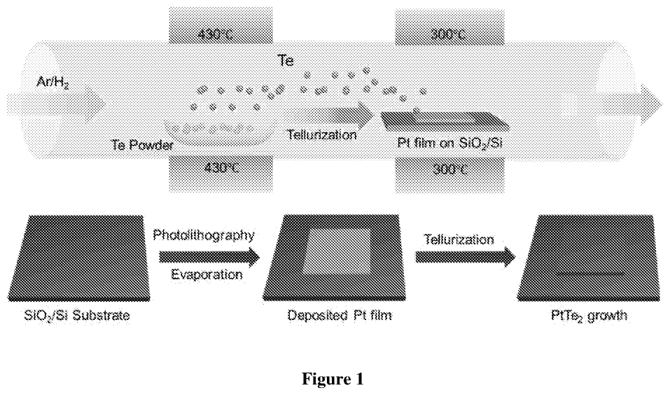

The tellurization process was carried out under an Ar/H₂ gas environment with a gas flow rate 100 sccm in a direction from the upstream location toward the downstream location. The Te powder was vaporized at 430° C. temperature for 15 minutes and subsequently deposited on the Pt surface of the Pt coated SiO₂/Si substrate. The PtTe layer is then annealed at a temperature of 450° C. for 75 mins under 100 sccm of Ar environment to form PtTe₂ and to remove excess Te from the surface. This process is schematically illustrated in FIG. 1.

Broadly, the process is illustrated as comprising three stages. In stage 1, a SiO₂/Si substrate is provided. In stage 2, a thin nanolayer of a transition metal (in this case Pt) is applied to a surface of the substrate using a physical vapor deposition. The Pt coated substrate is then treated to form a platinum dichalcogenide material. In this case, the dichalcogenide material is Te, and the process is generally referred to as a tellurization process. In step 3, and after the tellurization process, the PtTe₂ layer is formed. The tellurization process is illustrated in more detail in the inset image. In the tellurization process, a source of Te (in this case Te powder) is vaporized and entrained in a carrier gas of Ar/H₂ where it is carried downstream to the Pt coated SiO₂/Si substrate. The Pt coated SiO₂/Si substrate is held at a lower temperature of to promote deposition of the Te from the carrier gas onto a surface thereof to form a PtTe layer. The PtTe layer is then annealed to form the PtTe₂ layer as shown in stage 3.

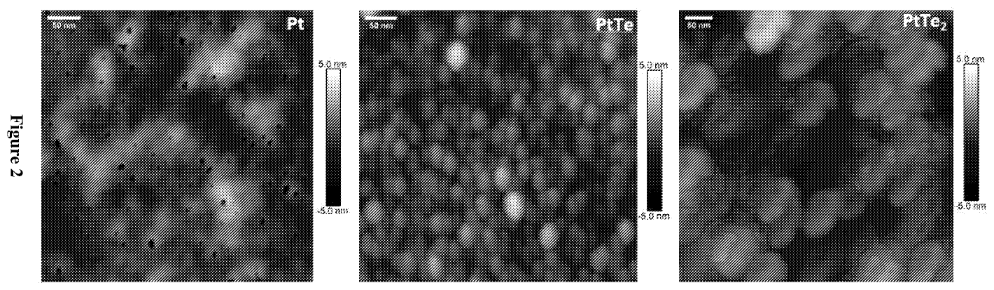

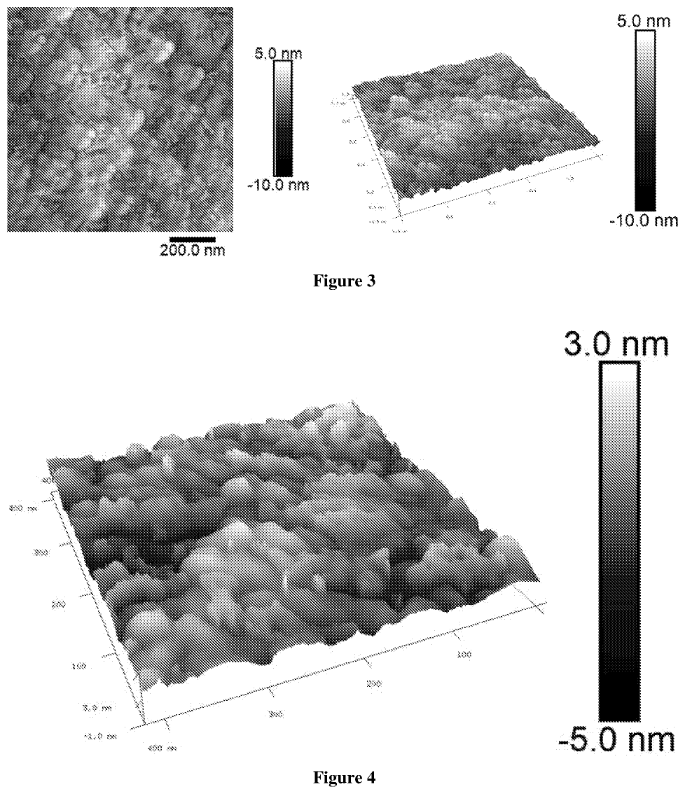

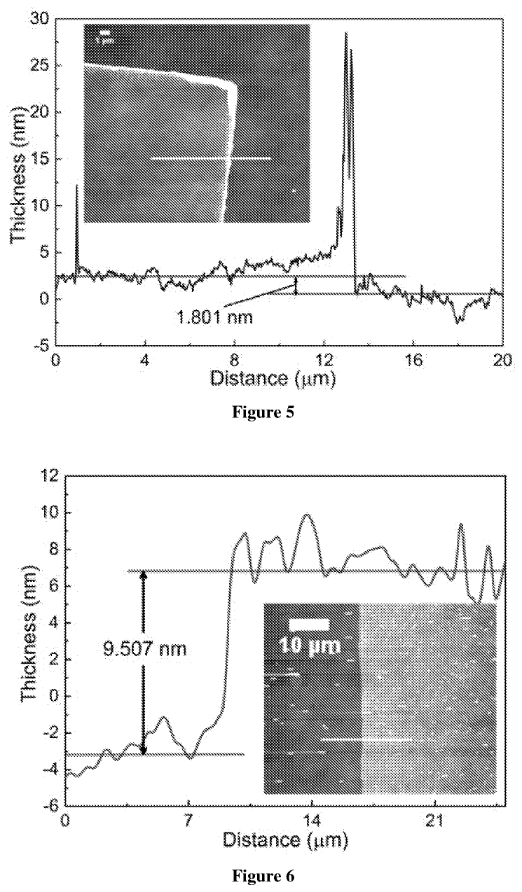

The surface and grain size of the Pt film, PtTe₂ layer and PtTe₂ layer observed using AFM with the resultant AFM images shown in FIG. 2. FIG. 2 shows the grain size changes from the Pt film, to the PtTe layer, and the final PtTe₂ layer. The average grain size in the PtTe₂ layer is about 200 nm in lateral dimension. From FIG. 2 it can be seen the Pt particles increase in size after the tellurization process confirming that Te atoms are attached to the Pt film and that the PtTe layer increases in stability after annealing to form the PtTe2 layer since no gaps are observed in the PtTe₂ layer after annealing. FIG. 3 and FIG. 4 are planar and 3D AFM images showing surface morphology and grain size in PtTe₂ layer. The 3D image shows out of plane orientation of the grains. The surface roughness of this film is 1.03 nm. FIG. 5 shows the thickness measurement of deposited Pt film and it is 1.801 nm. After forming the PtTe₂ layer the thickness is increased to 9.507 nm as shown in FIG. 6.

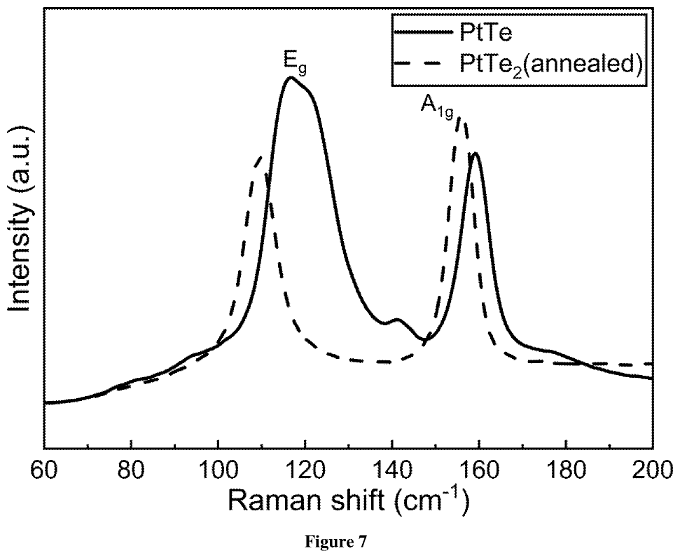

FIG. 7 shows the Raman spectrum of before and after annealing to form the PtTe₂ layer. As can be seen, the Raman shift of tellurized PtTe layer is found 116.71 cm⁻¹ and 159.78 cm⁻¹ for E_{g} and A_{1g} modes respectively. After annealing and formation of the PtTe₂ layer, the Raman E_{g} and A_{1g} peaks become sharper and the position of the peaks moves to 109.15 cm⁻¹ and 156.16 cm⁻¹ respectively. These results confirm the formation of PtTe₂.

The skilled person will appreciate that whilst this example reports the formation of a thin film of PtTe₂ on a planar surface, the method may be adapted to form a thin film of PtTe₂ on a three-dimensional structure or surface, or otherwise coat at least a portion of a three-dimensional structure with a thin film of PtTe₂.

### Example 2

This example reports fabricating a field effect transistor (FET) device from the PtTe₂ layer formed in Example 1.

To form the sensor element, the PtTe₂ layer was fabricated into a field effect transistor (FET) device using a photolithography process whereby a 7/100 nm of Ti/Au layer was deposited onto a portion of the PtTe₂ layer via ebeam evaporation process to make metal electrode contacts. The fabricated PtTe₂ FET device channel length and width were 40 μm and 50 μm respectively. The FET device was then annealed at 200° C. for 2 hours under 10/100 sccm of Ar/H₂ to reduce contact resistance.

A thin 50 nm of Al₂O₃ layer was also deposited via a photolithography and evaporation method to cover the metal electrodes for the purpose of minimizing interaction between the metal electrodes and the environment.

For the characterization of the FET device, a drain-source (V_{ds}) and back-gate (V_{g}) voltage were applied to the FET device and the output and transfer characteristics of the device were observed.

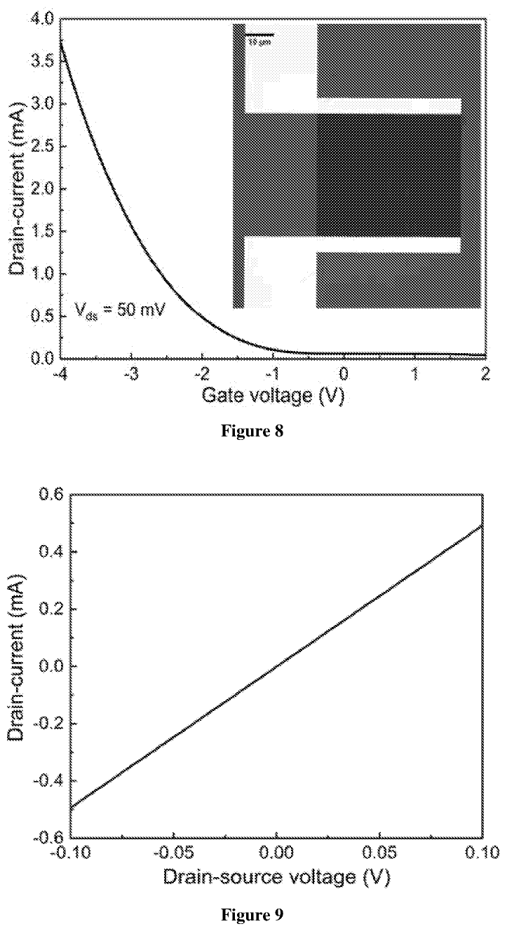

FIG. 8 shows the transfer characteristics curve of FET device as a function of V_{g} which was varied from −4 V to 2 V at a constant V_{ds} of 0.05 V. The inset is an optical image of the FET device.

The measured carrier mobility of FET device was 413 cm²V⁻¹s⁻¹. It is noted that this value is higher than the theoretically calculated value of 367 cm²V⁻¹s⁻¹ for multi-layer PtTe₂. The difference between the experimental value and the theoretically calculated value is thought to be due to the differences in the physical characteristics of the experimental and theoretical structures, e.g. the theoretical structures are single crystal structures.

FIG. 9 shows the output characteristics curve of the FET device as function of V_{ds} and I_{d}. As can be seen, I_{d} linearly decreases with V_{ds} in accordance with ohms law. The carrier mobility of the FET device was found to linearly increase with voltage. The conductivity of the device was found to be 3.72×10⁶ s·m⁻¹ which is much higher than the previously reported value of 1.7×10⁶ s·m⁻¹ in Wang, M., et al., Wafer-Scale Growth of 2D PtTe2 with Layer Orientation Tunable High Electrical Conductivity and Superior Hydrophobicity. ACS Applied Materials & Interfaces, 2020. 12(9): p. 10839-10851. The difference in conductivity is thought to be a consequence of 2D grain orientation and lack of annealing, and 3D grain orientation and annealing in the films disclosed herein.

The subthreshold voltage of the FET device was calculated to be 204.3 mV dec⁻¹.

FET devices were also fabricated with three different channel lengths of 10 μm, 20 μm and 45 μm to observe the variation of carrier mobility and current on/off ratio with the channel length. The carrier mobility of these FET devices was found to be 225 cm²V⁻¹s⁻¹, 361 cm²V⁻¹s⁻¹and 278 cm²V⁻¹s⁻¹respectively. Notably, the 20 μm channel length showed the highest carrier mobility.

### Example 3

This example reports the conversion of the FET device in Example 2 into a sensor for detecting liver cancer.

Alpha-fetoprotein (AFP) plays an important role to diagnosis the liver cancer clinically. Thus, to form the sensor, antibodies of AFP were immobilized on the surface of the PtTe₂ layer of the FET device using (3-Aminopropyl) triethoxysilane (APTES) and gold nanoparticles (AuNPs). A schematic representation of the overall process for forming a functionalized PtTe₂ FET sensor for detecting AFP proteins and shown in FIG. 10.

For surface modification, the FET device fabricated in Example 2 was immersed into a solution comprising 0.4 mL of APTES mixed with 19/1 mL of ethanol/DI solution for 2 hours. The device was then washed with DI water and dried with N₂ air. Subsequently, the device was heated at 120° C. for 5 mins in an Ar environment.

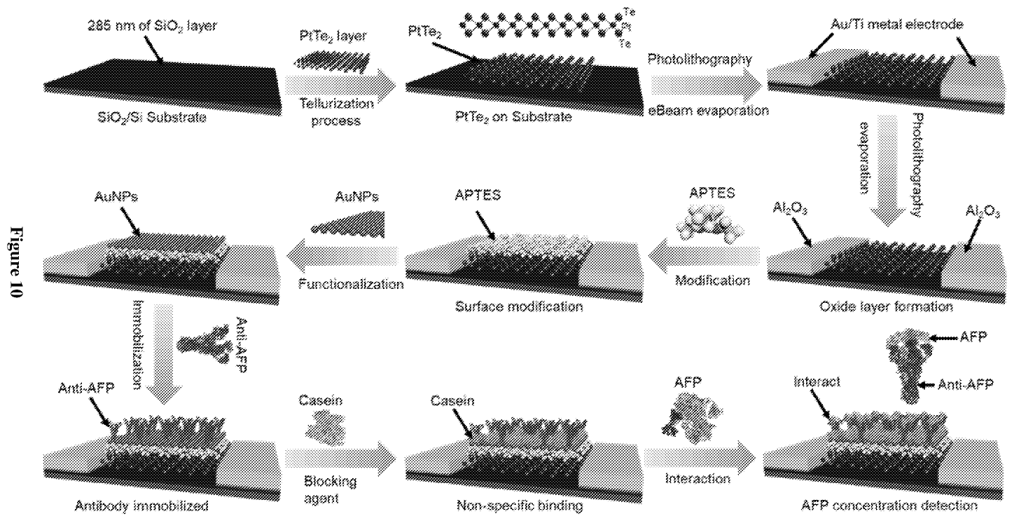

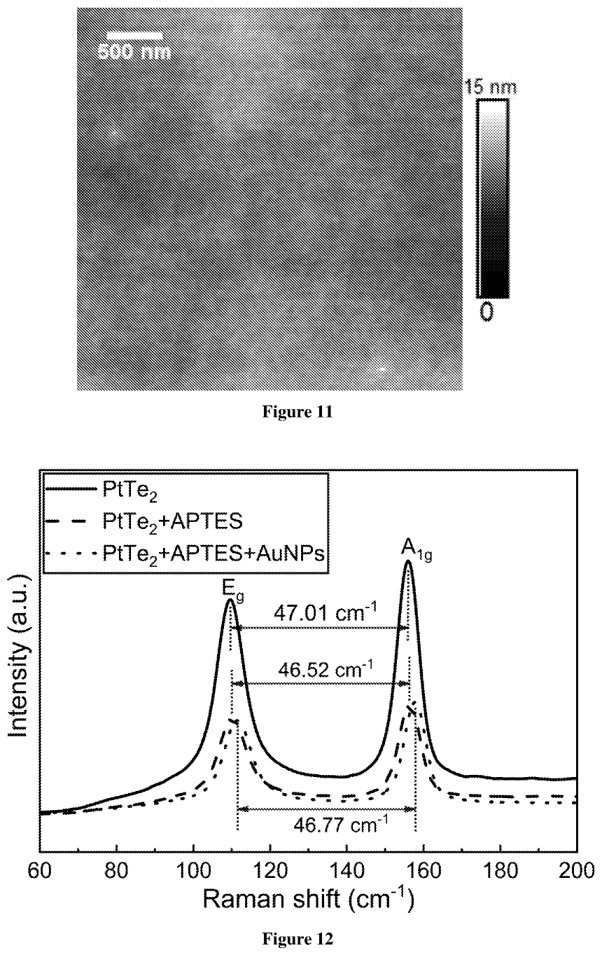

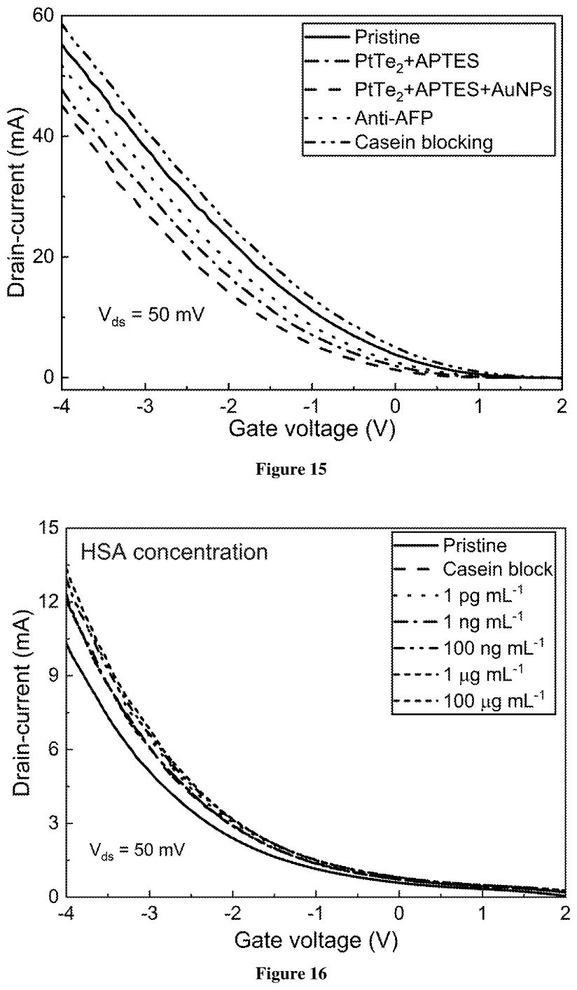

FIG. 11 shows the APTES modified PtTe₂ conductive surface and FIG. 12 shows the Raman spectrum of the PtTe₂ layer before and after surface modification with APTES. The E_{g} peak moved from 109.15 cm⁻¹ to 110.05 cm⁻¹ and 156.16 cm⁻¹ to 156.57 cm⁻¹ for A_{1g}. The difference between two peaks changes from 47.1 cm⁻¹ to 46.52 cm⁻¹ after modification of PtTe₂ surface with APTES. This result is due to the negative charge of APTES induced on the PtTe₂ surface because APTES provided amino group (—NH₂ moiety) based negative pole which electrostatically pushes electrons away from the APTES/PtTe₂ interface. Negatively charged APTES reduced the conductance of the PtTe₂ channel that observed in transfer characteristics curve that is shown in FIG. 15 that results drain current decreased of PtTe₂ FET surface.

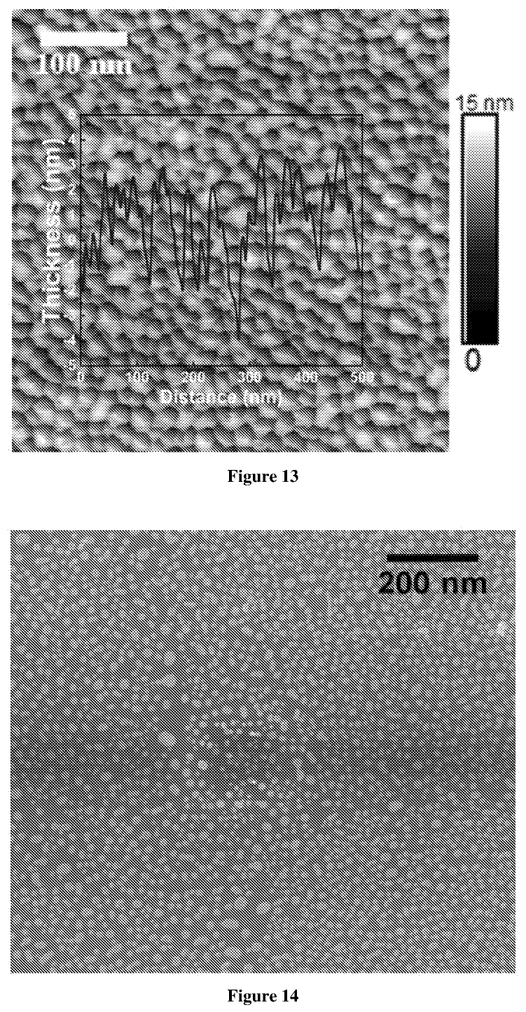

The APTES functionalized PtTe₂ surface was then further functionalized with AuNPs. AuNPs plays an important role in adsorbing and stabilizing antibodies. For the surface functionalization, AuNPs were deposited onto the APTES modified PtTe₂ via using ebeam evaporation process with deposition rate is 0.1 Å/s. Unexpectedly, the AuNPs were found to adsorb at high density. The AFM image in FIG. 13 shows the thickness of the formed AuNPs and the SEM image in FIG. 14 confirms the highly dense AuNPs formed on the APTES/PtTe₂ surface. It is thought that the presence of grain boundaries and increased surface area due to grains projecting out of plane from the surface contribute to the high surface density of AuNPs.

A higher surface density of AuNPs is beneficial since this increases the total amount of antibodies that can be adsorbed to the FET device and thus increases the sensitivity of the sensor to a target protein.

Referring back to FIG. 12, it is observed that Raman peaks shifted from 110.05 cm⁻¹ to 111.38 cm⁻¹ and 156.57 cm⁻¹ to 158.15 cm⁻¹ for E_{g} and A_{1g} respectively after functionalization of AuNPs on the APTES/PtTe₂ surface. The difference between the E_{g} and A_{1g} peaks is increased to 46.77 cm⁻¹. This result is likely due to the dense AuNPs pushing electrons away from the conductive surface. The drain current of PtTe₂ FET sensor decreased (shown in FIG. 15) and there was a reduction in conductance with Vₜₕ¬shifted. It is thought this is also likely due to the effect of the AuNPs pushing electrons from the conductive surface.

Subsequently, AFP antibodies were immobilized on AuNP functionalized surface. To achieve this, the AuNP functionalized surface was treated with a solution comprising 100 μg mL⁻¹ of anti-AFP.

When the negatively charged anti-bodies of AFP absorbed on the functionalized PtTe₂ surface the threshold voltage is positively shifted through inducing hole carriers in the PtTe₂ surface. In particular, FIG. 15 shows that the drain current of the FET device increased adsorption of the anti-AFP and increased the conductance of PtTe₂ surface.

A blocking agent of casein solution was introduced onto anti-AFP immobilized surface for non-specific binding and to ensure selective detection of AFP proteins through interaction with anti-AFP. The drain-current of the PtTe₂ sensor was been increased by adding casein solution on the conductive surface which in turn increased the conductance of the surface by shifting the threshold voltage. For specificity and selective detection of AFP protein, a control experiment was conducted at different concentration of human serum albumin (HSA). No current changes observed while adding HSA proteins as shown in FIG. 16. This result confirms that casein blocking agent plays an important role in reducing the non-specific binding and improving the efficiency of the selectiveness of the detection.

The functionalized FET device was then fabricated into a microfluidic device using photolithography and soft lithography processes to etch a microfluidic channel therein.

### Example 4

This example reports the use of the device of Example 3 to diagnose liver cancer via detection of AFP proteins.

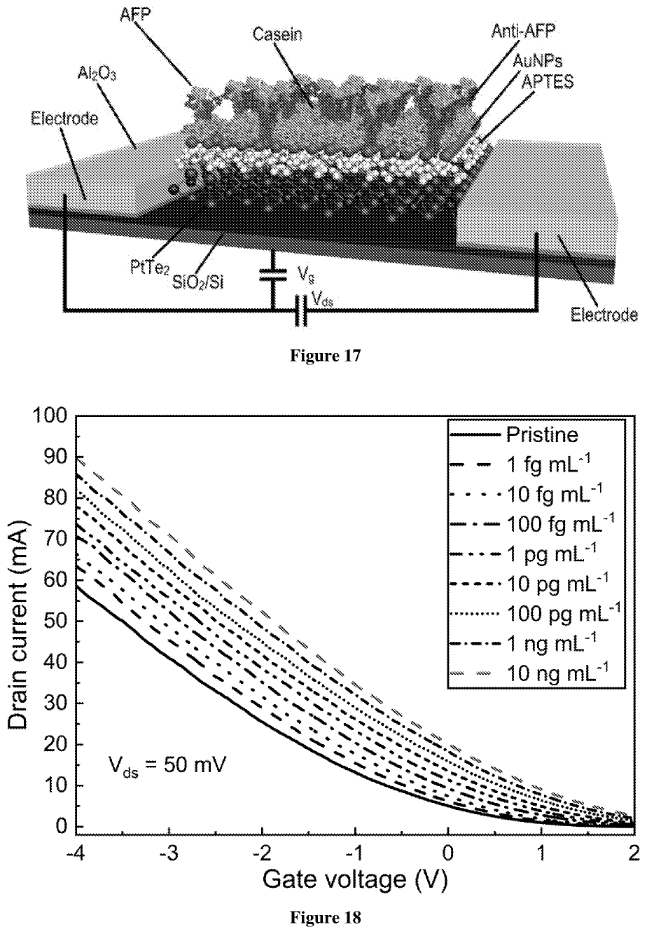

For the detection of AFP protein, 1 fg mL−1-10 ng mL−1 concentration of AFP proteins in PBS solution was passed through the microfluidic channel with a flow rate of 10 μL/min and incubation time of 30 min. FIG. 17 shows the schematic illustration AFP proteins detection with the functionalized FET device.

After incubation, the transfer and output characteristics of the sensor were measured by applying a V_{g} and V_{ds}. FIG. 18 shows the transfer characteristics curve of functionalized FET device as a function of AFP concentration. Notably, the functionalized FET device is able to detect concentration of AFP proteins of 1 fg mL⁻¹ which is 500 times lower than previously reported.

It is observed that the drain current of functionalized FET device linearly increases with increasing AFP protein concentration. This occurs due to a change in conductance of the PtTe₂ conductive channel. In particular, the sensing mechanism of the functionalized FET device is believed to occur due to a change in the carrier density of the PtFe2 layer due to an antigen binding or otherwise interacting with the immobilized antibodies with which the channel is functionalized. In particular, and without wishing to be bound by theory, the inventors are of the view that this binding provides an electrostatic effect that affects the electron behavior in the channel which causes the change in carrier density.

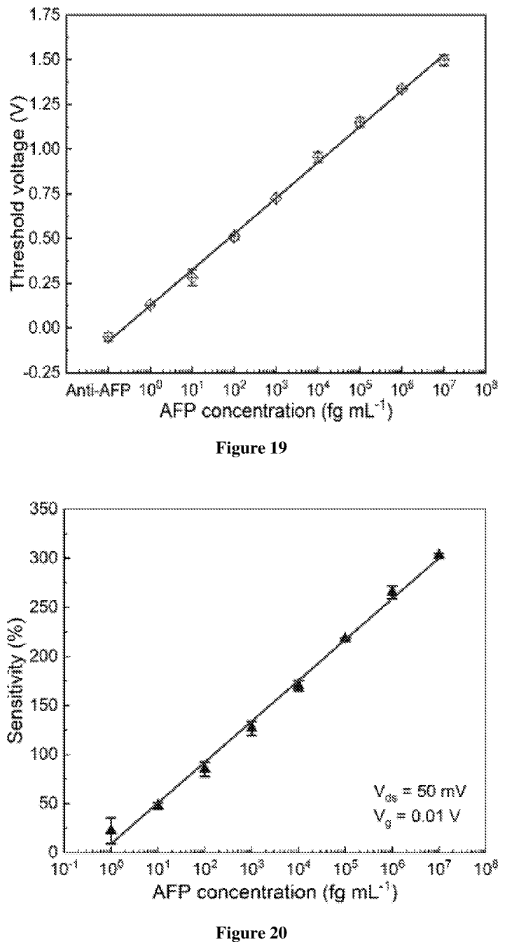

These results can be explained by a positively shifted threshold voltage and increasing number of hole carriers of the conductive surface. FIG. 19 shows the average threshold voltage changes as a function of AFP protein concentration and it is observed that threshold voltage positively changed while AFP proteins interacted with anti-AFP due to change in the charge carriers of the PtTe₂ conductive surface.

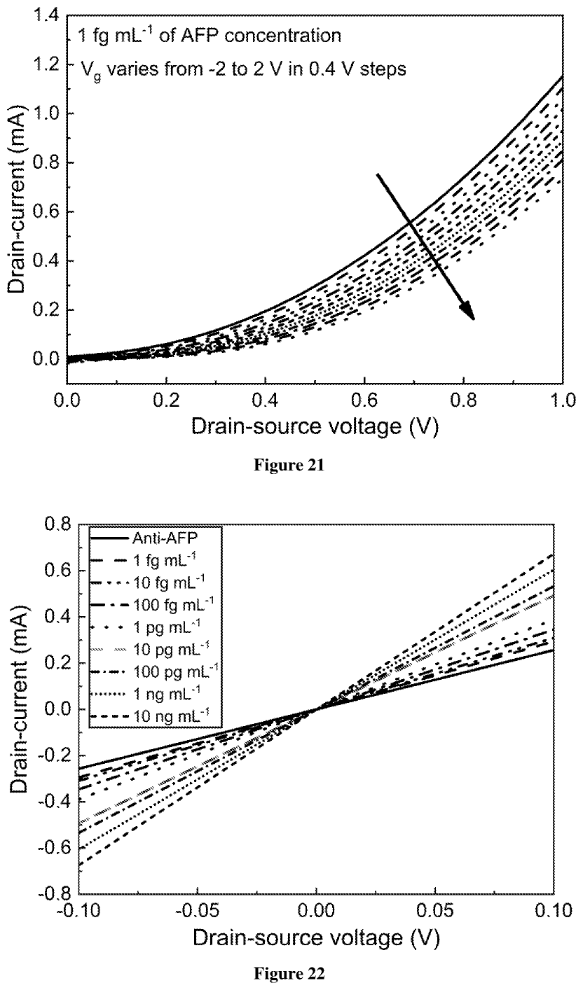

The sensitivity of the PtTe₂ device with AFP concentration was calculated as a function of AFP concentration and is shown in FIG. 20. The sensitivity of the functionalized FET sensor is 22.13% for low concentrations of AFP proteins e.g. at 1 fg ml⁻¹, and up to 302.69% for concentrations at 1 ng mL⁻¹. This result show that the functionalized FET device is highly sensitive to low concentrations of AFP protein in PBS solution. FIG. 21 shows the output characteristics of the functionalized FET sensor for 1 fg mL⁻¹ with variation in gate voltage. The results show that the functionalized FET device is able to detect low concentration with high sensitivity. The output characteristics of functionalized FET sensor for different concentration of AFP proteins as a function of drain-source voltage is shown in FIG. 22 and it is confirmed that la is increasing with an increasing of AFP concentration by increasing the conductance of PtTe₂ conductive surface.

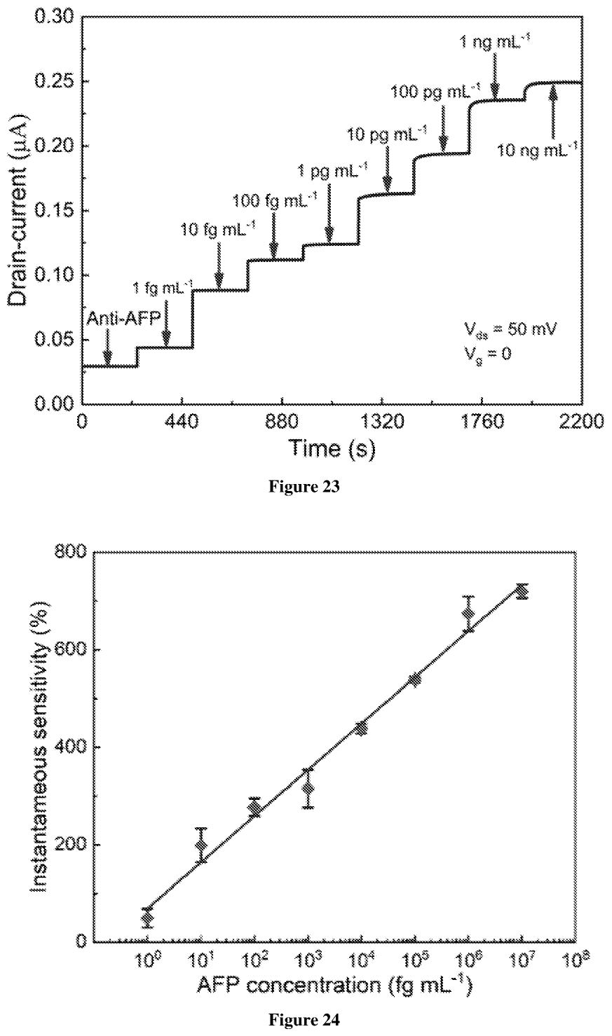

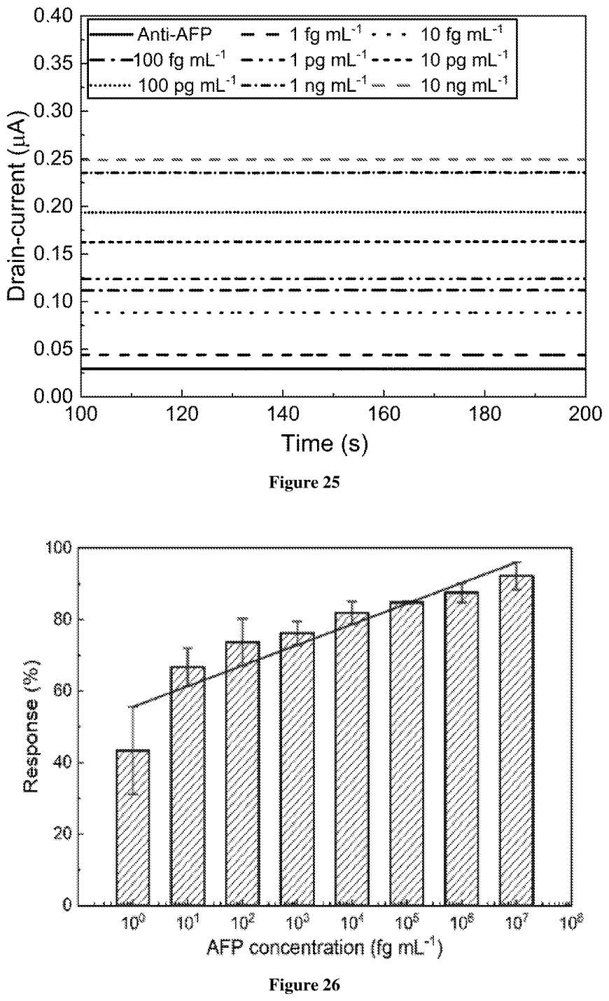

FIG. 23 shows the time-dependent response curve of the response of the functionalized FET device as a function of AFP concentration at 50 mV of drain-source voltage. It is observed that the drain current of PtTe₂ sensor linearly increases with increasing AFP concentration and that the factionalized FET device is able to detect concentrations of AFP of 1 fg mL⁻¹ as the drain current is increased from 0.03 μA to 0.04 μA. Without wishing to be bound by theory, the inventors are of the view that this result occurs due to a change in carrier density and conductance of the conductive surface of the PtTe₂ channel. The response time of the functionalized FET device was about 3˜4 seconds after interacting with the AFP and the drain current has stabilized in about 20 seconds. The instantaneous sensitivity calculated based on changes drain-current with time and average sensitivity has shown in FIG. 24. As can be seen, the sensitivity of the functionalized FET sensor was 49.20% and 719.31% at AFP concentrations of 1 fg mL⁻¹ and 10 ng mL⁻¹ respectively. Therefore, the functionalized FET sensor is highly sensitive to low concentration of AFP proteins and has potential use in point-of-care applications to diagnosis early stage liver cancer. FIG. 25 shows the stabilized drain-current with time where different concentrations of AFP introduced on the surface. The results show that the stability of the drain-current increases with increasing the AFP concentration. The response of the functionalized FET sensor as a function of AFP concentration and stabilized current is shown in FIG. 26. The response of functionalized FET sensor is 33.14% and 88.19% at AFP concentrations of 1 fg mL⁻¹ and 10 ng mL⁻¹ respectively.

### Example 5

This example reports the testing of large 1 mm×1 mm PtTe₂ films of the invention. The PtTe₂ material for the devices reported below has been prepared using the approach discussed in the examples above, and is thus expected to exhibit similar features in terms of characterisation.

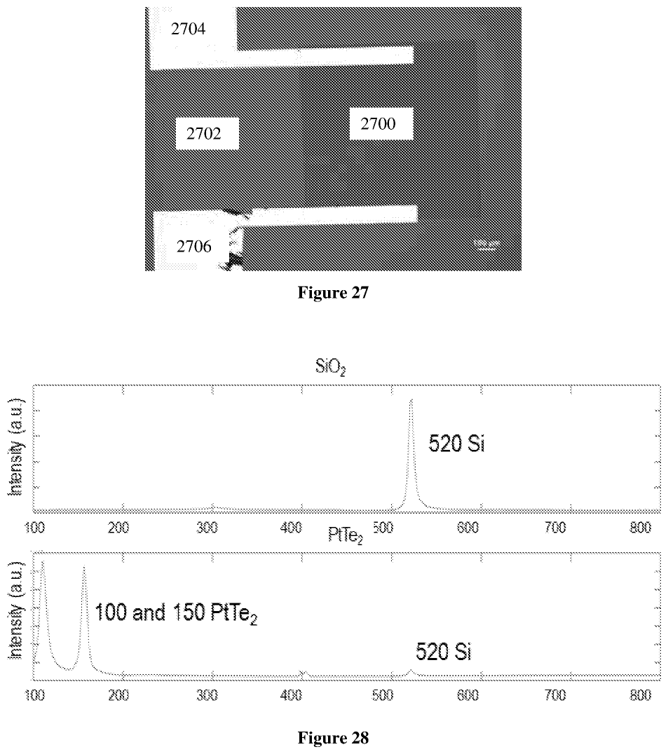

FIG. 27 is an image of a 1 mm×1 mm deposition of a 9 mm thick PtTe₂ film 2700 on a silicon substrate 2702 with electrical contacts 2704 and 2706 formed from gold. The scale bar in FIG. 27 represents 100 microns. The Raman spectra shown in FIG. 28 confirms that the film is PtTe₂.

The PtTe₂ film was tested for electrical sensitivity against a standard silicon film to determine the effectiveness of the PtTe₂ film in sensor applications. A typical field effect transistor (FET) arrangement was adopted with the PtTe₂ and amorphous Si layer with thickness of 30 nm forming the channel of the respective FET devices. The surfaces of the PtTe₂ and Si layers were additionally functionalized with Au/Pd nanoparticles. To achieve this, after forming the semiconductor channel, a 3-5 nm thick Au layer was deposited on the channel, followed by a 3-5 nm thick Pd layer using an e-beam evaporator. The samples were then annealed at 200° C. under Nitrogen for 20 mins. During this annealing step, the Au—Pd films transformed into self-assembled nanoparticles.

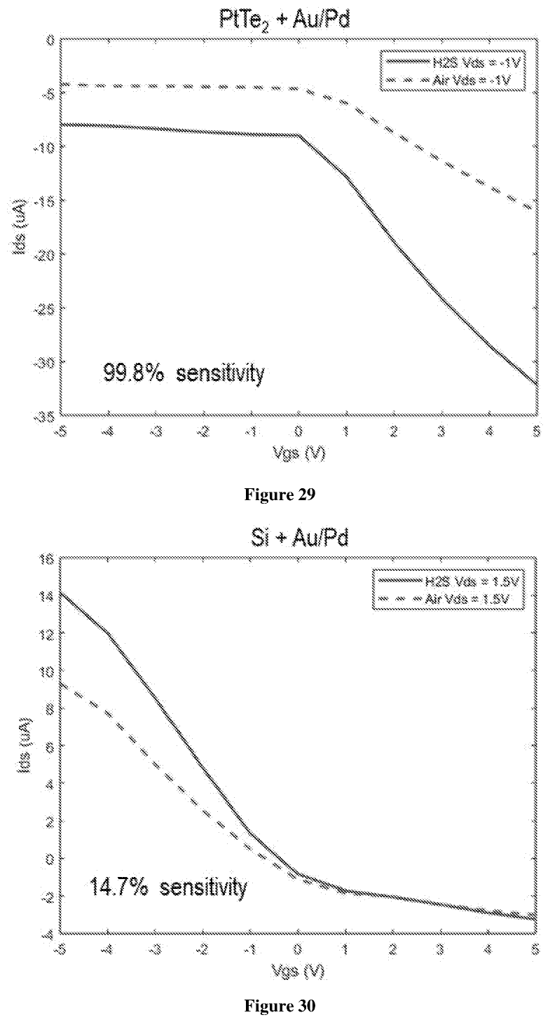

The PtTe₂ FET sensors were advantageously found to operate at lower bias than Si FETs (low power consumption, energy efficient): Si devices operate at 6V bias whereas PtTe₂ devices operate at 1 V bias. The sensitivity testing results are shown in FIG. 29 and FIG. 30 for both PtTe₂ and Si devices, the results show that the FET including the Si channel for gate bias range of −5 to 5 V for Si exhibited a sensitivity of 14.7%, whereas the PtTe₂ devices exhibited a sensitivity of 99.8%.

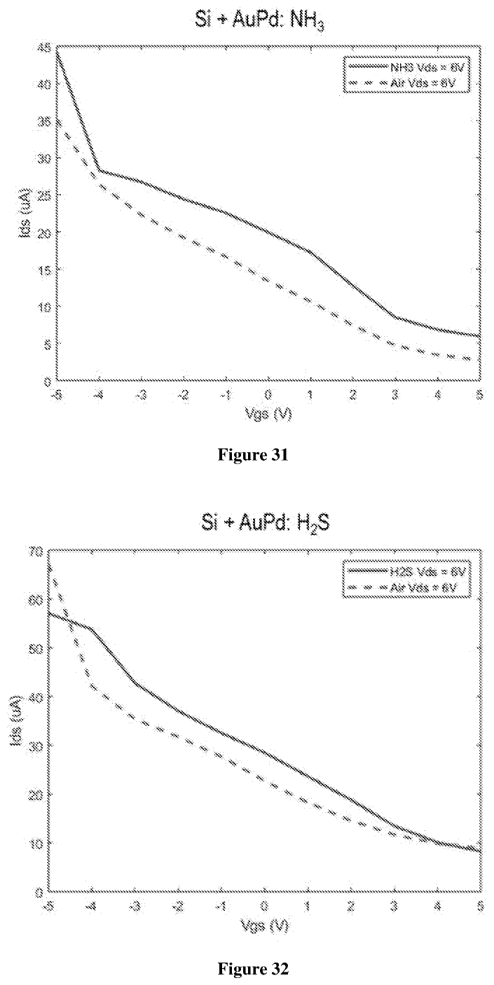

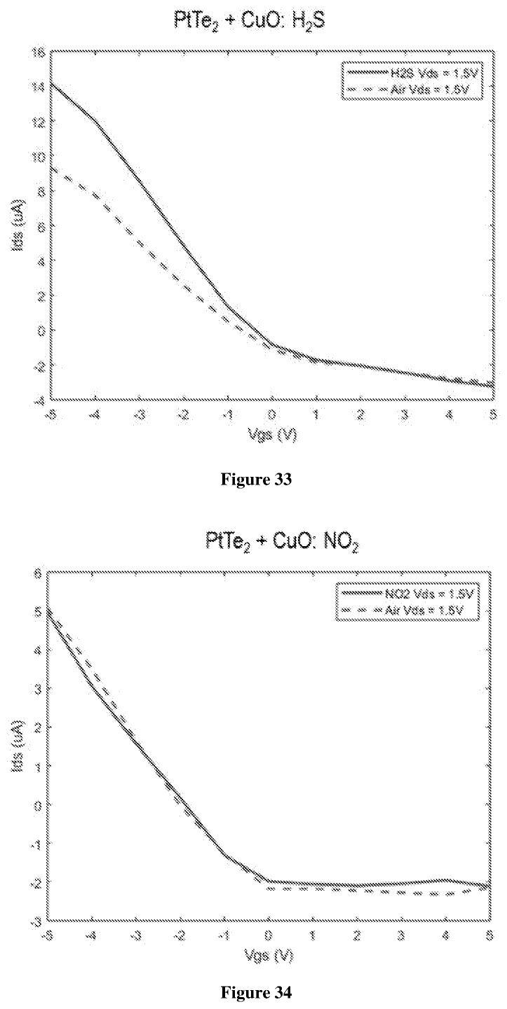

The inventors have also found that the PtTe₂ layer can be beneficially functionalized to provide sensor selectivity. That is, through different surface functionalization, it is possible to tailor a sensor to achieve selective detection. In particular, the inventors found that functionalization of the PtTe₂ surface with Au—Pd nanoparticles results in a sensor that response to a number of gases. However, selectivity can be achieved by adopting different surface functionalization. FIGS. 31, 32, 33, and 34 are graphs showing the results of the sensitivity of two FETs with a channel formed from a silicon layer functionalized with Au—Pd nanoparticles and two FETs with a channel formed from a PtTe₂ layer according to the invention functionalized with CuO nanoparticles respectively. The results show that the FETs with the channel formed from the silicon layer did not exhibit any selectivity between NH₃ and H₂S gas whereas the FETs with the channels formed from the PtTe₂ layer did exhibit selectivity.

It will be understood that the invention disclosed and defined in this specification extends to all alternative combinations of two or more of the individual features mentioned or evident from the text or drawings. All of these different combinations constitute various alternative aspects of the invention.

1. A structure comprising a substrate having a polycrystalline transition metal di-chalcogenide nanolayer disposed on a substrate surface, wherein the polycrystalline transition metal di-chalcogenide nanolayer has a surface, and a portion of the plurality of grains project out of plane from the surface.

2. The structure of claim 1, wherein the polycrystalline transition metal di-chalcogenide nanolayer is formed from a plurality of grains, the plurality of grains having a D50 of from about 20 nm up to about 400 nm.

3. The structure of claim 1, wherein the polycrystalline transition metal di-chalcogenide nanolayer has an average thickness of from about 4 nm up to about 20 nm.

4. The structure of claim 1, wherein the polycrystalline transition metal di-chalcogenide nanolayer is substantially continuous.

5. The structure of claim 1, wherein the polycrystalline transition metal di-chalcogenide nanolayer is formed from a transition metal di-chalcogenide of the form MX₂, where M represents a transition metal selected from the group consisting of: Mo, Pt, Sn, W, and Zr, and X represents a chalcogenide selected from the group consisting of: S, Se, and Te.

6. The structure of claim 1, wherein the substrate is an electrically insulating material or a semiconducting material or a metal.

7. The structure of claim 1, wherein the substrate is selected from the group consisting of silica, alumina, or a polymer.

8. The structure of claim 1, wherein (i) the substrate has a planar surface, and the polycrystalline transition metal di-chalcogenide nanolayer is disposed on the planar surface, or (ii) the substrate has a 3D structure with a non-planar surface, and the polycrystalline transition metal di-chalcogenide nanolayer is disposed on the non-planar surface.

9. The structure of claim 1, wherein the polycrystalline transition metal di-chalcogenide nanolayer has a surface roughness of from about 0.5 nm up to about 2 nm.

10. A device comprising:
a structure comprising a substrate having a polycrystalline transition metal di-chalcogenide nanolayer disposed on a substrate surface, wherein the polycrystalline transition metal di-chalcogenide nanolayer has a surface and a portion of the plurality of grains project out of plane from the surface,
a source electrode, and
a drain electrode,
wherein the source electrode and the drain electrode are separated from one another by, and are each arranged in electrical contact with, the polycrystalline transition metal di-chalcogenide nanolayer.

11. The device of claim 10, wherein the surface of the polycrystalline transition metal di-chalcogenide nanolayer is functionalized with a probe for detection of an analyte.

12. The device of claim 11, wherein:
the probe is configured to alter electron mobility and/or conductivity and/or transconductance of the polycrystalline transition metal di-chalcogenide nanolayer on detection of the analyte; and/or
wherein the probe is selected from the group consisting of a ligand, a surfactant, a nanoparticle, a polymer, an oligomer an antibody, a gas molecule, or a combination thereof.

13. (canceled)

14. An assay method comprising the step of:
detecting an analyte with the structure of claim 1 or a device comprising the structure or claim 1.

15. The method of claim 14, further comprising:
contacting a sample receiving surface of the structure or device with a sample;
measuring electron mobility of the polycrystalline transition metal di-chalcogenide nanolayer; and
determining the presence of the analyte in the sample based on a change in the electron mobility of the polycrystalline transition metal di-chalcogenide nanolayer.

16. A method for forming a structure comprising a polycrystalline transition metal di-chalcogenide nanolayer, the method comprising:
providing a structure having a transition metal surface;
depositing a chalcogenide on the transition metal surface under an atmosphere at a deposition temperature in the range of 300° C. to 500° C.; and
annealing the chalcogenide on the transition metal surface at a temperature in the range of 300° C. to 500° C. for a time sufficient to form the polycrystalline transition metal di-chalcogenide nanolayer.

17. The method of claim 16, wherein the step of depositing the chalcogenide on the transition metal surface is a physical vapor deposition process.

18. The method of claim 16, wherein the structure further comprises a substrate, and the method further comprises depositing a transition metal on the substrate surface under an inert atmosphere at a temperature in the range of 300° C. to 500° C. to form the structure having a transition metal surface.

19. The method of claim 16, wherein the step of depositing the transition metal of the substrate surface is a physical vapor deposition process.

20. The method of claim 16, wherein the annealing temperature is higher than the deposition temperature.

21-22. (canceled)

23. The structure of claim 1, wherein the structure is capable of being used as a sensor, a catalyst, a thermoelectric device, a photodetector, an energy storage device, a super capacitor, a petrochemical water splitting device, or an optoelectronic device.
